(19) United States
(12) Patent Application Publication
(10) Pub. No.: US 2018/0054185 A1
(43) Pub. Date: Feb. 22, 2018

(54) ANTENNA IMPEDANCE MATCHING USING NEGATIVE IMPEDANCE CONVERTER AND PRE- AND POST-MATCHING NETWORKS

(71) Applicant: Smart Antenna Technologies Ltd., Birmingham (GB)

(72) Inventors: Sampson Hu, Birmingham (GB); Liang Wan, Birmingham (GB)

(21) Appl. No.: 15/560,755

(22) PCT Filed: Mar. 24, 2016
(86) PCT No.: PCT/GB2016/050842

§ 371 Date: Sep. 22, 2017

(30) Foreign Application Priority Data
Mar. 25, 2015 (GB) 1505058.6
Mar. 25, 2015 (GB) 1505059.4
Jul. 24, 2015 (GB) 1513085.9

(51) Int. Cl. H03H 11/28; H03H 11/10; H03H 11/34; H03F 1/56

(52) U.S. Cl. CPC H03H 11/28; H03H 11/10; H03F 2200/369; H03F 1/565; H03H 11/34

(57) ABSTRACT

There is disclosed a matching network for connecting an electrically small antenna to an RF source or load. The matching network includes a negative impedance converter, a pre-matching network for connecting the negative impedance converter to the antenna and a post-matching network for connecting the negative impedance converter to the RF source or load. The pre-matching network comprises a combination of capacitors and/or inductors to transform both a real part and an imaginary part of an impedance of the antenna. The negative impedance converter is configured to cancel the transformed imaginary part of the impedance of the antenna. The post-matching network comprises a combination of capacitors and/or inductors to transform a residual real part of the impedance of the antenna to match an impedance of the RF source or load. There is also disclosed an antenna system comprising a plurality of antenna radiating elements each having an associated feed, at least one of the feeds being connected to an RF source or load by way of an active matching circuit comprising a pre-matching network, a negative impedance converter and a post-matching network.

This invention relates to matching networks to match electrically small antennas to RF sources and, in particular, to the provision of a pre-matching network and a post-matching network in combination with a negative impedance converter. Certain aspects relate to the provision of negative impedance converters in matching circuits for multiple-feed reconfigurable antenna systems to enable impedance matching across several different frequency bands.

### BACKGROUND

Electrically small antennas can be generally classified as TM (transverse magnetic) and TE (transverse electric) mode antennas. For a TM mode small antenna, which is widely used in wireless communication systems, the input impedance is considerably reactive with a small real part. It is therefore critical to match the antenna to the receiver or transmitter to maximise the total efficiency in the frequency range of interest.

Normally, an electrically small TM mode antenna can be characterised by or represented as a series connected combination of a resistor, a capacitor and an inductor. FIGS. 1 and 2 show that, at low frequencies, the reactance can equally be represented by a series connected capacitor and inductor, with the capacitor playing a dominant role in the reactance. The resistor represents the resistance of the radiating element of the antenna.

There are two different ways to match a highly reactive antenna of this type. One approach is conventional passive matching, where a large series inductor Lₑₓₜ is placed between the antenna and the signal port as a necessary component. However, the resistive loss that is introduced by the inductor Lₑₓₜ dramatically degrades the total efficiency. In fact, even with lossless inductors, the match is effective over only extremely small instant bandwidths because the reactive part of the electrically small antenna cannot be neutralised over a broad frequency band with passive components (the real part of the impedance is much smaller than the imaginary part). This is illustrated in FIG. 3.

The other approach uses an NIC (negative impedance converter) in an attempt to cancel the reactance of the antenna. This is a type of non-Foster impedance matching, and is illustrated in FIG. 4.

There is a relationship between antenna size and the realisable bandwidth as defined by the Chu limit (Chu, L. J.; “Physical limitations of omni-directional antennas”; Journal Applied Physics 19: 1163-1175; December 1948). The Chu limit gives the relationship between the radius of the circle that completely circumscribes an antenna and the Q of the antenna. However, McLean (McLean, J. S.; “A re-examination of the fundamental limits on the radiation Q of electrically small antennas”; IEEE Transactions on Antennas and Propagations; Vol. 44; No. 5; pp. 672-676; May 1996) redefined how the Q of an antenna should be calculated, and this is given in equation 1.1:

$$Q = \frac{1}{( {k}^{3} {a}^{3} )} + \frac{1}{( ka )} \qquad ( 1.1 )$$

where k is the wave number and a is the radius of a sphere that completely circumscribes the antenna as shown in FIG. 5.

McLean's equation is a derivation from the original Chu limits equations. There has also been much research into ways of improving the gain of an antenna through the use of matching networks, but this is also bounded by the Harrington limits (Harrington, R. F.; “Effect of antenna size on gain, bandwidth and efficiency”; Journal of Research of the National Bureau of Standards—D. Radio Propagation; vol. 64D; p. 12; 29 Jun. 1959) on antennas as given in:

G=(ka)²+2ka (1.2)

The Chu limit can be related to the antenna bandwidth by rewriting the Q of the antenna as shown in equation 1.3:

$$Q = \frac{{f}_{c}}{Δ f} = \frac{1}{( {k}^{3} {a}^{3} )} + \frac{1}{( ka )} \qquad ( 1.3 )$$

where f_{c} is the antenna centre frequency at resonance and Δf is the bandwidth of the antenna.

Comparing equation 1.1 with equation 1.3, it can be seen that reducing the radius of the sphere which translates to a physical reduction in the antenna size, the antenna bandwidth also reduces. The reduction in size means that the antenna radiation resistance also reduces, and this in turn leads to a reduction the antenna efficiency. From equation 1.2, it is clear that antenna gain is also proportional to the antenna size a.

These two fundamental limits on the antenna make it difficult to provide a small antenna with a low Q (wideband). However, more and more devices these days require smaller antennas and there is need for these antennas to still have wide usable bandwidths.

Passive matching networks help to match antennas, but because they involve resonating the reactive part of the antenna with passive elements, they only give a good match at specific frequencies. Away from the specific frequency, the antenna return loss decreases. This necessitates the use of multiple or reconfigurable matching networks to cover wide frequency bands. However, using non-Foster elements could help provide continuous wideband matching because unlike Foster elements, the slope of the reactance versus frequency of a non-Foster element is always negative as shown in FIG. 4.

With these properties, non-Foster elements are able to cancel out completely the reactance of other elements and antennas because of the difference in slope and direction of rotation on the Smith chart.

One implementation of non-Foster elements is through the use of NICs (negative impedance converters). NICs were first proposed by Linvill (Linvill, J. G.; “Transistor negative-impedance converters”; Proc. IRE; vol 41, pp 725-729; 1953). The Linvill NIC consists of two transistors connected in a common base configuration. “Common base” or “common gate” refers to a specific input and output setup of a transistor in amplifier applications. In a Linvill type NIC, the RF input terminal is connected to the emitter or source of one transistor, and the RF output terminal to the emitter or source of the other transistor (in fact, since an NIC is normally a bidirectional device, it does not matter which terminal is used as the RF input and which as the RF output). The reactance to be inverted is connected between the two collectors or drains, and the base or gate of each transistor is connected to the collector or drain of the other transistor in the form of a feedback path. The emitters or sources form the two ports of the NIC. The circuit schematic of the NIC is shown in FIG. 6.

A typical conventional Linvill type NIC matching arrangement is shown in FIG. 7.

However, the present Applicant has found that conventional Linvill type NIC matching circuits as shown in FIG. 7 are not always ideal enough to generate the precise negative impedance that is required in particular antenna applications. This can result in lower total efficiency, higher noise figures and potential instability.

Earlier work by the present Applicant has investigated the use of negative components generated by NICs to cancel the input reactance of networks including an antenna and a subsequent pre-matching impedance transformer. However, this cancellation covers only a single continuous frequency band, which may not always be sufficient in today's multiple band communications environment.

### BRIEF SUMMARY OF THE DISCLOSURE

Viewed from a first aspect, there is provided a matching network for connecting an electrically small antenna to an RF source or load, the matching network comprising a negative impedance converter, a pre-matching network for connecting the negative impedance converter to the antenna and a post-matching network for connecting the negative impedance converter to the RF source or load, wherein the pre-matching network comprises a combination of capacitors and/or inductors to transform both a real part and an imaginary part of an impedance of the antenna, the negative impedance converter is configured substantially to cancel the transformed imaginary part of the impedance of the antenna, and wherein the post-matching network comprises a combination of capacitors and/or inductors to transform a residual real part of the impedance of the antenna to match an impedance of the RF source or load.

Previous investigations by the present Applicant into the use of negative impedance converters for cancelling the imaginary part of the antenna impedance have encountered significant problems due to an increase in noise and a loss of efficiency. These problems have been encountered by others, and have presented a barrier to the adoption of negative impedance converters in practical applications.

It has surprisingly been found, after diligent further investigation, that these problems can be mitigated by the introduction of a pre-matching network between the antenna and the negative impedance converter.

The pre-matching network may take any appropriate form, comprising a combination of capacitors and/or inductors and/or resistors, suitable for transforming an impedance, as will be understood by those of ordinary skill in the art.

Advantageously, the pre-matching network includes at least one tuneable element, for example a switchable or tuneable capacitor, so as to allow the level of impedance transformation to be varied for different RF frequencies.

In preferred embodiments, the pre-matching network is configured to transform the in-band real part of the antenna impedance to a higher level and the in-band imaginary part of the antenna impedance to a lower level with respect to the original antenna impedance.

The negative impedance converter is configured substantially to cancel the transformed imaginary part of the antenna impedance at the relevant frequency or frequency band.

The post-matching network is configured to transform the residual real part of the transformed antenna impedance to match the impedance of the RF source or load, which is typically 500 in standard devices. It will, however, be understood that the residual real part of the transformed antenna impedance may be matched to other values where appropriate.

Through appropriate circuit design, the pre-matching network can be configured so that the real part of the transformed antenna impedance is kept fairly flat or constant across the operational frequency band.

Advantageously, the imaginary part of the transformed antenna impedance has a zero crossing frequency in the operational frequency band. If the neighbourhood of the zero crossing frequency is chosen to be the transmitting frequency channel, the negative impedance converter can achieve nearly maximum power efficiency and good linearity.

In order to obtain good wideband matching performance and high transmit power efficiency at different frequency channels, the pre-matching network is preferably tuned by way of tuneable components in order to lock the transmit frequency channel to the neighbourhood of the zero reactance frequency.

The negative impedance converter and the post-matching network may also be provided with tuneable components and tuned accordingly for best performance.

The RF source or load may be a transceiver port, a transmitter port or a receiver port.

Taking the antenna radiation resistance as Rₐₙₜ, and the antenna reactance as Xₐₙₜ, the pre-matching network is configured to transform Rₐₙₜ to a transformed antenna radiation resistance Rₐ, and to transform Xₐₙₜ to a pre-matching transformed reactance Xₜ.

The pre-matching induced loss resistance can be denoted as RI1, while the post-matching induced loss resistance can be denoted as RI2.

Considered a transceiver as an RF source, the RF output power of the transceiver can be denoted as P_{RFout}.

The negative impedance converter is advantageously configured to cancel the transformed in-band antenna reactance Xₜ and the induced loss resistance on either side of the negative impedance converter. Ideally, the impedance presented by the negative impedance converter is therefore: −[(RI1+RI2)+jXₜ]. Ideally, the antenna RF output power is equal to the transceiver RF output power.

Therefore, the magnitude of the RF current flowing through the negative impedance converter, t_{RF}, is:

$${i}_{RF} = \sqrt{\frac{2 {P}_{RFout}}{{R}_{a}}}$$

and the magnitude of the RF voltage across the negative impedance converter, v_{RF}, is:

$${v}_{RF} = \sqrt{{( Rl 1 + R l 2 )}^{2} + {X}_{t}^{2}} \sqrt{\frac{2 {P}_{RFout}}{{R}_{a}}}$$

For a Linvill-type negative impedance converter comprising a pair of transistors in a common base configuration, in order to keep the negative impedance converter working in the linear region, it is necessary for the bias conditions (including the bias voltage and the bias current) on the functional transistors of the negative impedance converter to be:

I_{DS}≧t_{RF}

V_{DS}≧v_{RF}

Therefore the RF power efficiency of the negative impedance converter meets the following relationship:

$${η}_{NIC} - \frac{{P}_{RFout}}{2 {P}_{D C}} - \frac{{P}_{RFout}}{2 {V}_{DS} {I}_{DS}} \leq \frac{{R}_{a}}{4 \sqrt{{( Rl 1 + R l 2 )}^{2} + {X}_{t}^{2}}}$$

From the above equations, it can be concluded that the power efficiency is proportional to the transformed antenna radiation resistance Rₐ, and reaches a maximum when the pre-matching transformed antenna reactance Xₜ is zero.

Accordingly, the pre-matching network is advantageously configured to transform the antenna reactance Xₐₙₜ to a transformed antenna reactance Xₜ that is zero or close to zero.

In addition, it has surprisingly been found that the provision of a pre-matching network between the antenna and the negative impedance converter can result in a significant reduction in noise.

Although the NIC matching circuit architectures for noise reduction and for power efficiency are generally similar, the actual function of the pre-matching network and design constraints are different in each case.

When implemented in order to effect noise reduction, the pre-matching network transforms the antenna impedance so that the radiation-related real part is high, optionally as high as possible. It is usually the case that the higher the radiation-related real part, the lower the noise figure of the whole matching circuit. However, there is fundamentally some trade-off between the level of the transformed real part of the antenna impedance and the matched instant bandwidth that is actually achievable. When designing for noise reduction, it is not so critical to take account of the transformed imaginary part of the impedance.

When implemented in order to effect high power efficiency, the pre-matching network transforms the antenna impedance not only so as to obtain a high real part, but also to obtain a low imaginary part, optionally as low an imaginary part as possible. Typically, the highest efficiency is obtained at the frequency where the imaginary part of the antenna impedance is zero.

The negative impedance converter need not be a Linvill-type converter, but may instead be based around an operational amplifier or other appropriate circuitry. The important point is that the antenna reactance is transformed by the pre-matching network to a value close to zero for best efficiency and noise reduction.

Viewed from a second aspect, there is provided an antenna system comprising a plurality of antenna radiating elements each having an associated feed, at least one of the feeds being connected to an RF source or load by way of an active matching circuit comprising a pre-matching network, a negative impedance converter and a post-matching network.

The pre-matching network connects the negative impedance converter to the respective antenna feed, and the post-matching network connects the negative impedance converter to the RF source or load, which may be a transceiver port, a transmitter port or a receiver port.

The pre-matching network may comprise a combination of capacitors and/or inductors to transform both a real part and an imaginary part of an impedance of the respective antenna feed. The negative impedance converter may be configured substantially to cancel the transformed imaginary part of the impedance of the antenna. The post-matching network may comprise a combination of capacitors and/or inductors to transform a residual real part of the impedance of the antenna to match an impedance of the RF source or load.

In some embodiments, all of the feeds are connected to the RF source or load by way of an active matching circuit comprising a negative impedance converter. In these embodiments, active impedance matching is enabled for all of the feeds.

In other embodiments, at least one of the feeds is connected to the RF source or load by way of a passive matching circuit that does not include a negative impedance converter. The passive matching circuit may comprise a pre-matching network and a post-matching network as described in relation to the active matching circuit.

Where the RF load or source is a transceiver, the matching circuits may all be connected to a single transceiver port, or may be connected to different transceiver ports as required. In some embodiment, some matching circuits may be connected to one transceiver port, while other matching circuits may be connected individually to other transceiver ports. Where the RF load is a transmitter or a receiver, then connection may be made to a single transmitter or receiver port, or to different transmitter or receiver ports.

Each of the radiating antenna elements and their associated matching circuits are configured to operate in a predetermined continuous frequency band. The predetermined continuous frequency bands may be selected so as to give appropriate coverage for desired applications, for example to provide coverage of two or more of DVB-H, GSM710, GSM850, GSM900, GSM1800, PCS1900, SDARS, GPS1575, UMTS2100, WiFi, Bluetooth, LTE, LTA and 4G frequency bands.

The radiating antenna elements may be sized differently to each other and/or have different electrical sizes so as to provide a simple input impedance response at each frequency band to be matched. Because the radiating antenna elements are generally located close to each other, for example in a mobile handset or other portable device, the elements will tend to couple with each other to a greater or lesser degree during operation. Antenna coupling can be a serious problem in known multi-antenna devices, since it makes it much harder to provide effective impedance matching. This is because such coupling can change the impedance of any given antenna in unpredictable ways, depending on which of the other antennas is operating at any given time.

The pre-matching networks have two main functions. The first is to decouple the antenna radiating elements over the frequency bands of interest at any given time. Typically, after decoupling, the input impedance after the pre-matching network in the relevant matching circuit is substantially independent of the matching networks connected after the pre-matching networks in the other matching circuits. The second function is to transform the antenna impedance to a level at which the negative impedance converter can easily cancel or substantially cancel the transformed reactance (the imaginary part of the impedance).

In order to enable the transformed reactance to be most effectively cancelled with the negative impedance converter, the transformed antenna impedance preferably has the following characteristics: i) the transformed real part should be higher than the real part of the impedance prior to transformation, and should be relatively flat across the frequency band of interest; and ii) the transformed imaginary part should increase monotonically from negative to positive over each frequency band of interest. In order to facilitate this, the antenna impedance of each antenna radiating element should be optimised for its associated frequency band by, for example, selecting or adjusting the physical size of the antenna radiating element. An antenna radiating element configured to handle a lower frequency band will be larger than an antenna radiating element configured to handle a higher frequency band, thereby helping to optimise the input impedances of the individual antenna radiating elements for their respective frequency bands.

The post-matching networks also have two main functions. The first is to match the impedance to the RF source or load (typically 50 ohms) after cancellation of the reactance in the negative impedance converter, or after transformation in a passive matching circuit. The second is to decouple the matching circuits from each other in embodiments where more than one matching circuit is connected to a single port, for example a single transceiver port.

### BRIEF DESCRIPTION OF THE DRAWINGS

Embodiments of the invention are further described hereinafter with reference to the accompanying drawings, in which:

FIG. 1 shows an electrically small antenna connected to a 50 ohm signal port;

FIG. 2 shows the antenna of FIG. 1 represented as an equivalent series connected resistor, capacitor and inductor;

FIG. 3 shows the arrangement of FIG. 2 provided with a passive impedance matching network, together with a plot of reactance against angular frequency;

FIG. 4 shows the arrangement of FIG. 2 provided with a non-Foster matching network comprising a negative capacitance, together with a plot of reactance against angular frequency;

FIG. 5 illustrates an antenna circumscribed by a sphere of radius a;

FIG. 6 is a schematic of a conventional Linvill-type negative impedance converter (NIC);

FIG. 7 shows a conventional NIC arrangement for matching an antenna to a transceiver;

FIG. 8 shows a matching network including a pre-matching network, an NIC and a post-matching network in accordance with the present disclosure;

FIG. 9 shows the main parts of the network of FIG. 8;

FIG. 10 shows one implementation of the network of FIG. 9;

FIG. 11 shows a detail of the NIC circuit of FIG. 10;

FIG. 12 shows a detail of the pre-matching circuit of FIG. 10;

FIG. 13 shows a plot of matching performance for the embodiment of FIG. 10 with a first set of capacitor values;

FIG. 14 is a plot showing the change of impedance values with frequency;

FIG. 15 shows the 3^{rd} order intermodulation distortion (IMD3);

FIG. 16 shows a plot of matching performance for the embodiment of FIG. 10 with a second set of capacitor values;

FIG. 17 is a plot showing the change of impedance values with frequency;

FIG. 18 shows the 3^{rd} order intermodulation distortion (IMD3);

FIG. 19 shows an outline schematic of an embodiment of the disclosure;

FIG. 20 shows the arrangement of FIG. 19 without a pre-matching circuit;

FIG. 21 shows the return loss for the arrangements of FIGS. 19 and 20;

FIG. 22 is a Smith chart for the arrangements of FIGS. 19 and 20;

FIG. 23 is a schematic outline of a first embodiment of the second aspect;

FIG. 24 is a schematic outline of a second embodiment of the second aspect;

FIG. 25 is a variation of the embodiment of FIG. 23;

FIG. 26 is a variation of the embodiment of FIG. 24;

FIG. 27 is a more detailed schematic of a variation of the first embodiment of the second aspect;

FIG. 28 shows the return loss at each transceiver port of the embodiment of FIG. 27;

FIG. 29 shows the total efficiency of the embodiment of FIG. 27;

FIG. 30 is a more detailed schematic of a variation of the second embodiment of the second aspect;

FIG. 31 shows the return loss at the single transceiver port of the embodiment of FIG. 30; and

FIG. 32 shows the total efficiency of the embodiment of FIG. 30;

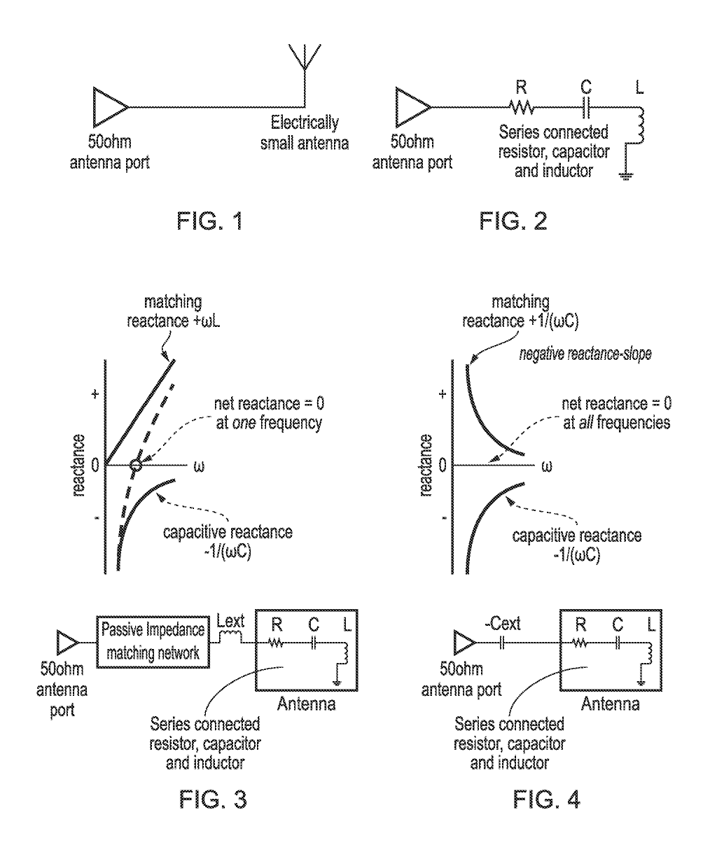

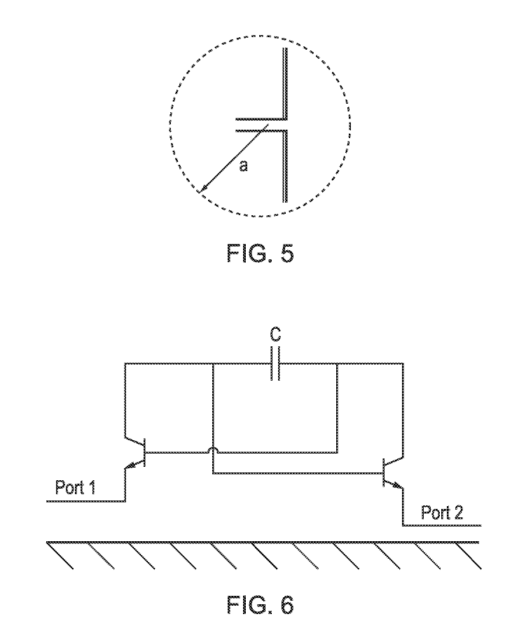

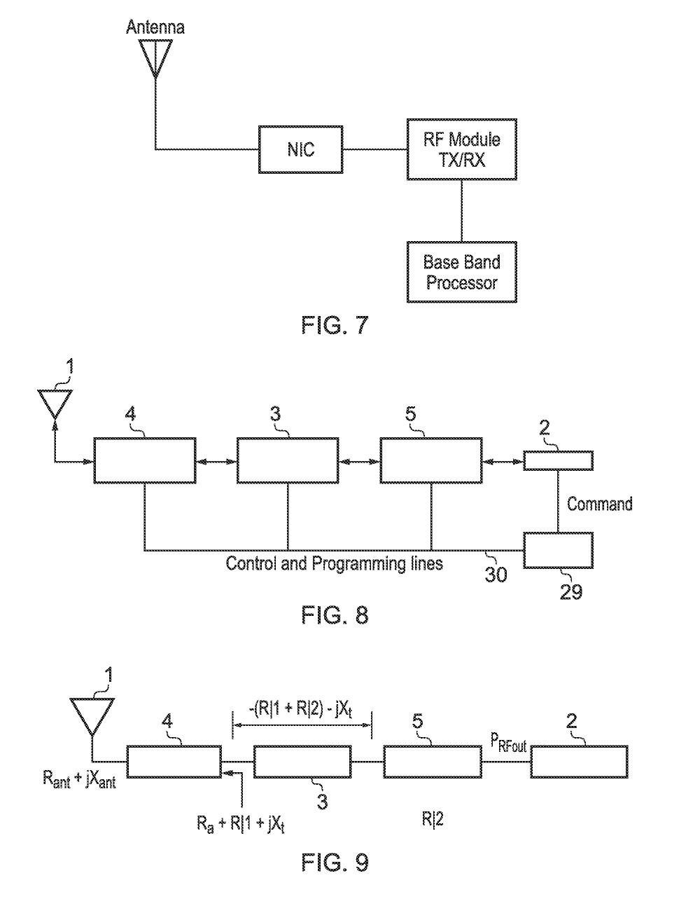

### DETAILED DESCRIPTION

FIG. 8 shows in schematic outline an embodiment of the present disclosure. An electrically small antenna 1 is connected to an RF transceiver 2 by way of a negative impedance converter (NIC) 3. A pre-matching network 4 is connected between the NIC 3 and the antenna 1, while a post-matching circuit 5 is connected between the NIC 3 and the transceiver 2. In preferred embodiments, one or more of the NIC 3, the pre-matching network 4 and the post-matching network 5 includes tuneable or switchable components such as tuneable or switchable capacitors or inductors. A system controller 29, for example a microprocessor or integrated circuit, is provided to control the transceiver 2 and the tuneable or switchable components in the NIC 3, pre-matching network 4 and/or post-matching network 5 by way of control and/or programming lines 30.

FIG. 9 shows the impedance transforming components of the embodiment of FIG. 8 in order to illustrate more clearly the desired function of each component. The antenna 1 has an antenna radiation resistance Rₐₙₜ and an antenna reactance Xₐₙₜ. The pre-matching network 4 is configured to transform the antenna radiation resistance Rₐₙₜ to a transformed antenna radiation resistance Rₐ, and to transform the antenna reactance Xₐₙₜ to a transformed antenna reactance Xₜ. The antenna impedance may be considered as Rₐₙₜ (the real part) plus Xₐₙₜ (the imaginary part). The pre-matching network 4 is configured to transform Xₐₙₜ to a value Xₜ that is zero or close to zero. Advantageously, the pre-matching network 4 will transform Rₐₙₜ to a higher value Rₐ. This is because the overall RF power efficiency of the NIC 3 is proportional to Rₐ, and for any given Rₐ will be at a maximum when Xₜ is zero. The post-matching circuit 5 is configured to transform the real part of the impedance at the output of the NIC 3 to match the impedance of the transceiver port 2, which is typically 50Ω.

Ideally, the NIC 3 is further configured to cancel the induced ohm loss resistance RI1 of the pre-matching network 3 and the induced ohm loss resistance RI2 of the post-matching network 4.

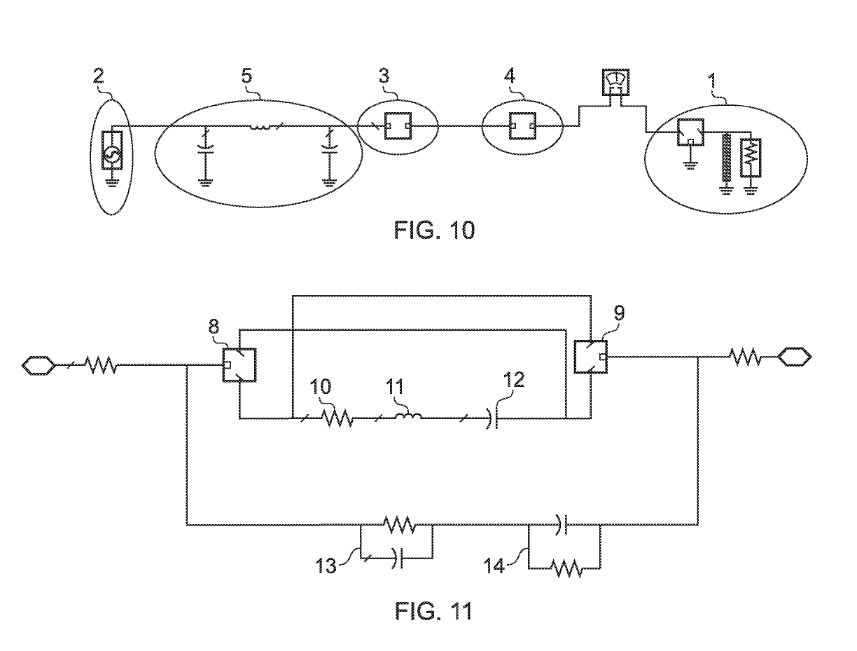

A specific implementation of the arrangement of FIG. 9 is shown in FIG. 10. The implementation comprises an antenna 1, a pre-matching network 4, an NIC circuit 3, a post-matching circuit 5 and a transceiver port 2.

FIG. 11 shows the NIC circuit 3 of FIG. 10 in more detail. The NIC 3 is a Linvill-type NIC comprising first and second transistors 8, 9 connected in a cross-over configuration as will be understood by those skilled in the art. A resistor 10, inductor 11 and switchable or tuneable capacitor 12 between the collectors or drains of transistors 8, 9. The negative impedance presented by the NIC circuit 3 can be adjusted by adjusting the capacitor 12. A parallel resistor-capacitor bank 13 is connected across the NIC 3 to provide an additional parallel passive impedance adjustment network, and an optional further parallel resistor-capacitor bank 14 may be connected in series with the first bank 13.

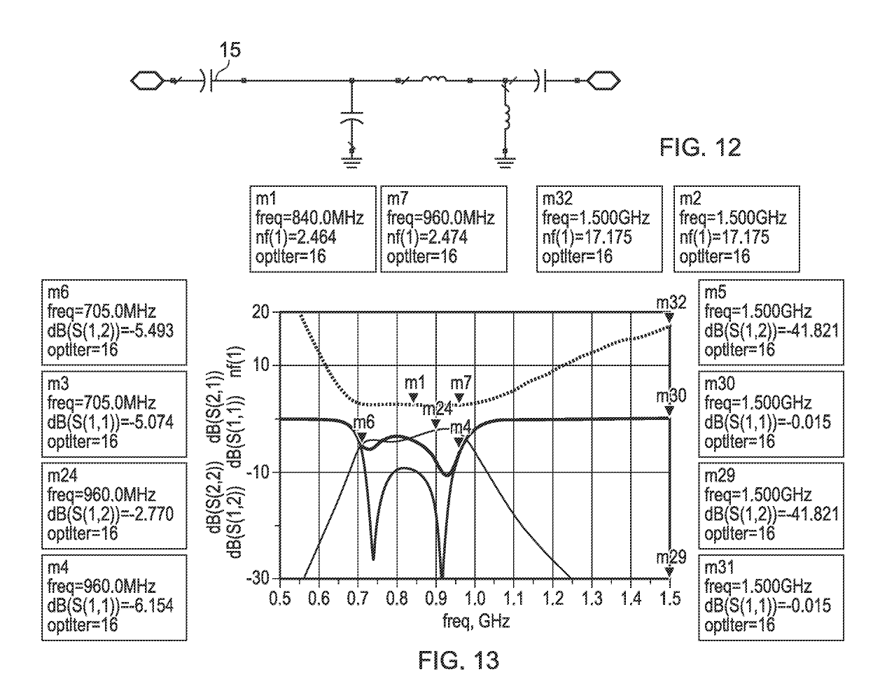

FIG. 12 shows the pre-matching network 4 of FIG. 10 in more detail. A switchable or tuneable capacitor 15 is provided so as to allow tuning.

It will be noted that the embodiment shown in FIG. 10 has only two switchable or tuneable capacitors 12, 15.

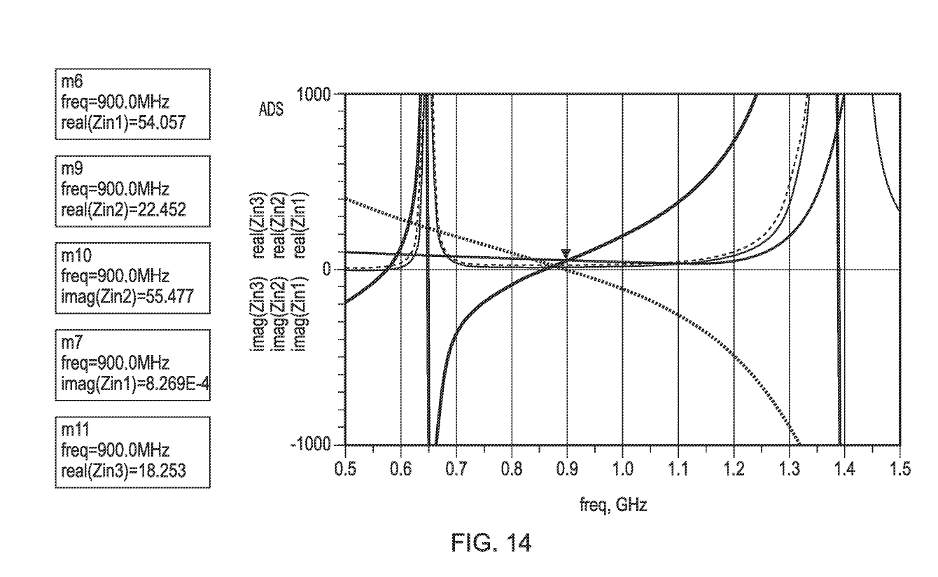

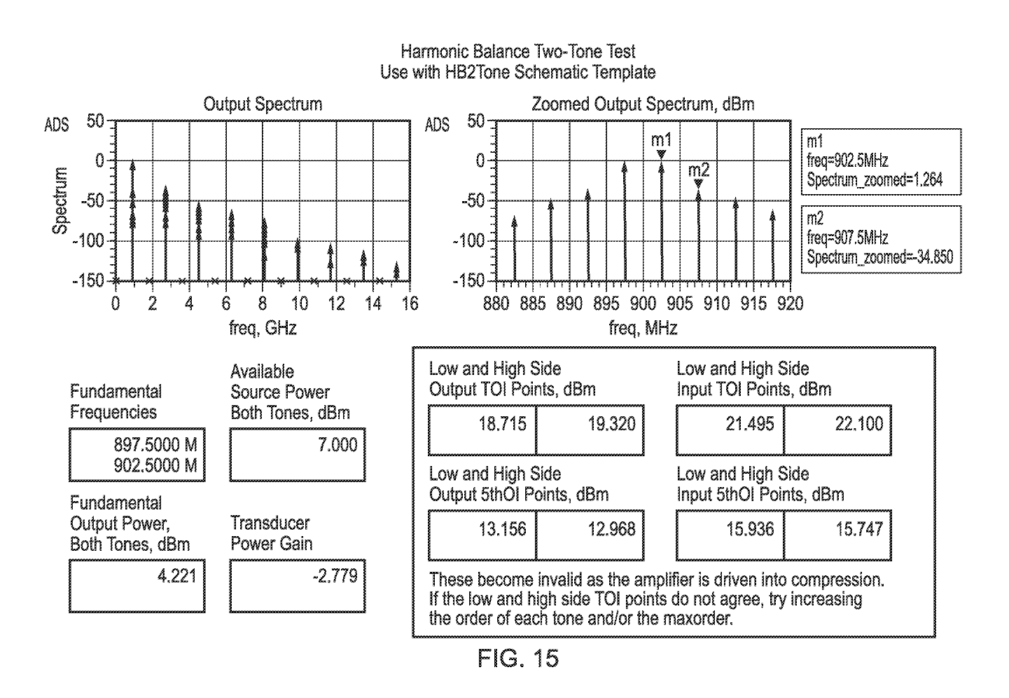

One exemplary set of results will now be described. The entire matching network of FIG. 10 is tuned to have a substantially zero reactance at around 900 MHz by setting the tuneable capacitor 12 in the NIC 3 to 0.34 pF, and the tuneable capacitor 15 in the pre-matching network 4 to 0.77 pF. The matching performance of this implementation is shown in FIG. 13, the impedances in FIG. 14 and the linearity in FIG. 15. The power efficiency at 900 MHz is found to be around 20%.

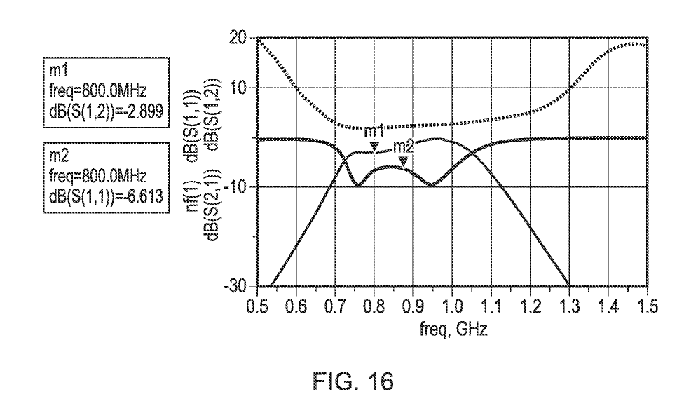

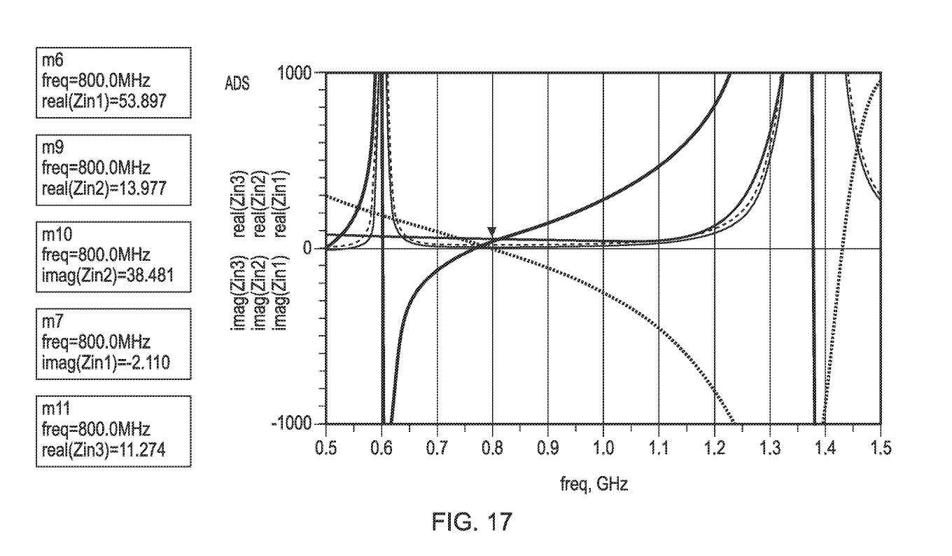

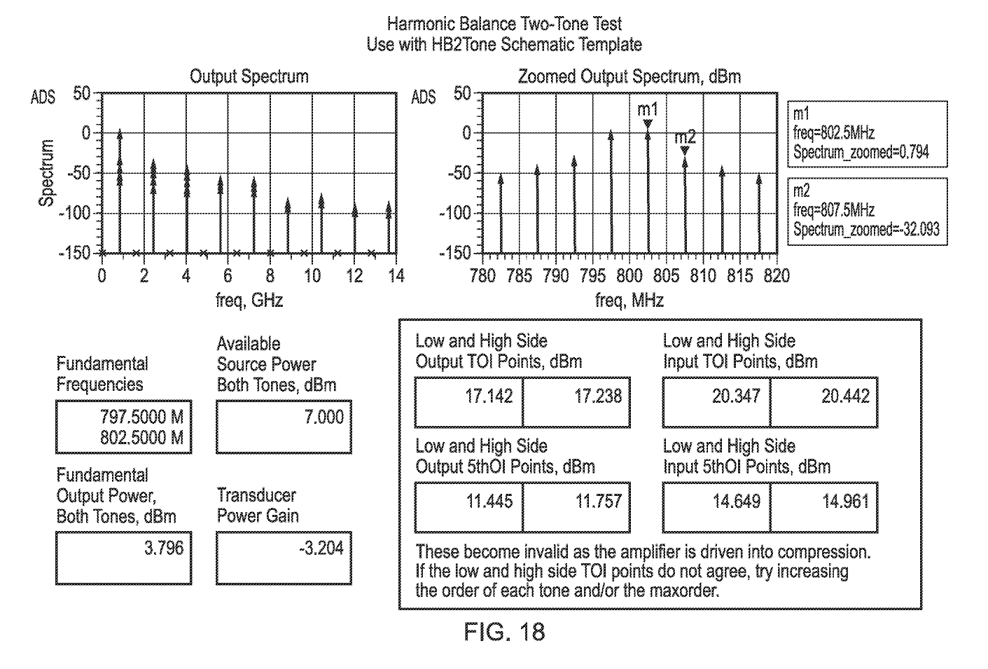

After tuning the capacitor 12 to 0.42 pF and the capacitor 15 to 1.17 pF, the matching performance as shown in FIG. 16 covers almost the same frequency band, and the impedance as shown in FIG. 17 has a different zero reactance frequency of 800 MHz. The linearity at 800 MHz is shown in FIG. 18, and the power efficiency is found to be 18.2%.

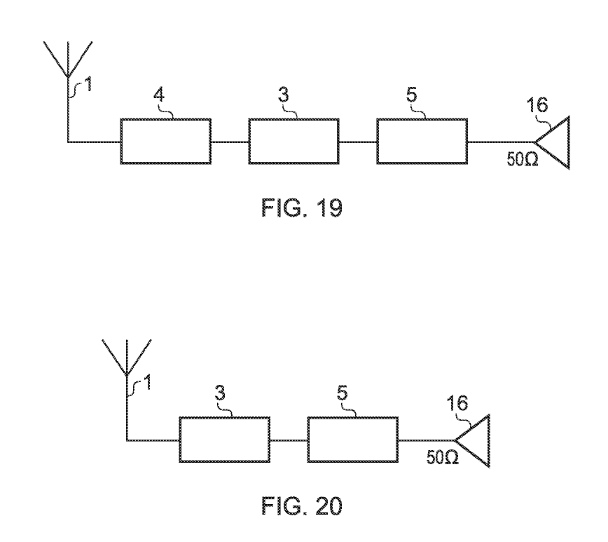

As well as improving power efficiency, embodiments of the present disclosure are effective in reducing noise. FIG. 19 shows a test arrangement comprising an antenna 1, a pre-matching network 4, and NIC 3, a post-matching network 5 and a 500 measurement port 16. FIG. 20 shows a comparative test arrangement similar to that of FIG. 19, but without a pre-matching network 4.

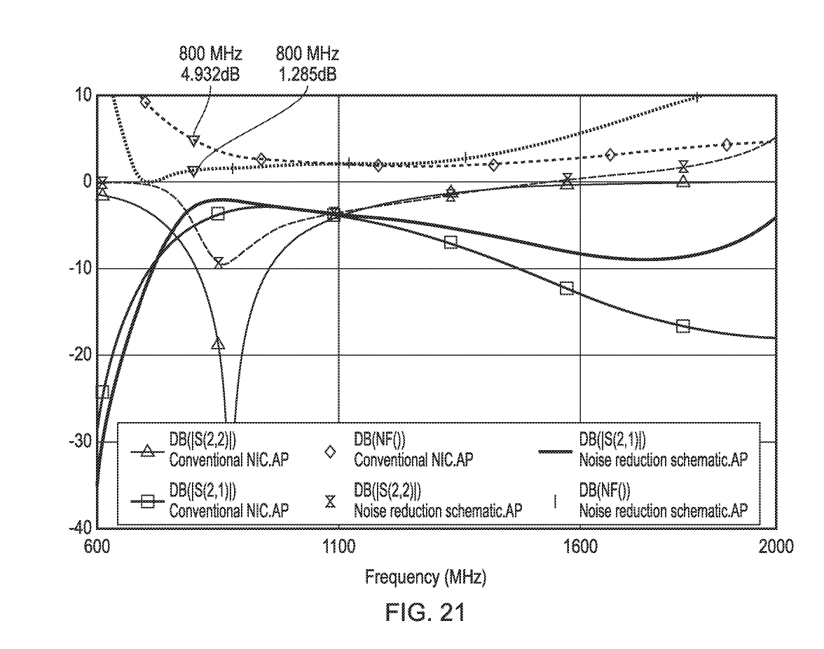

FIG. 21 is a return loss plot demonstrating that the arrangement of FIG. 19, with the pre-matching network 4, has a noise figure at 800 MHz of just 1.285 dB, in contrast to the noise figure of 4.932 dB for the arrangement of FIG. 20. Thus, an improvement in noise of approximately 3.8 dB is obtained, as well as an improvement in antenna efficiency.

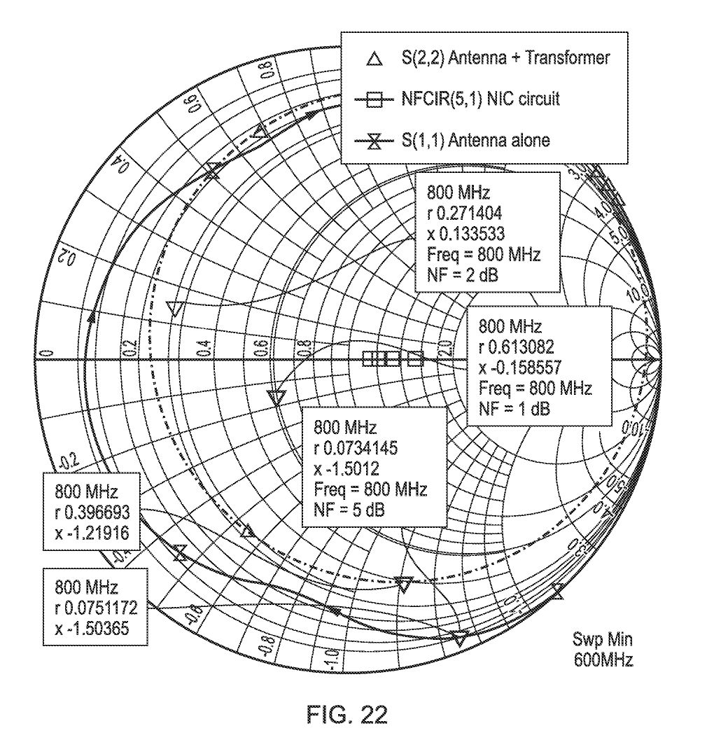

FIG. 22 is a Smith chart showing the noise circle of the NIC 3. It can be seen the antenna with the pre-matching circuit 4 lies between NF=1 dB to 2 dB, which that of the arrangement without the pre-matching circuit 4 lies just on the NF=5 dB circle. Improving the impedance match between the antenna 1 and the NIC 3 helps to reduce noise.

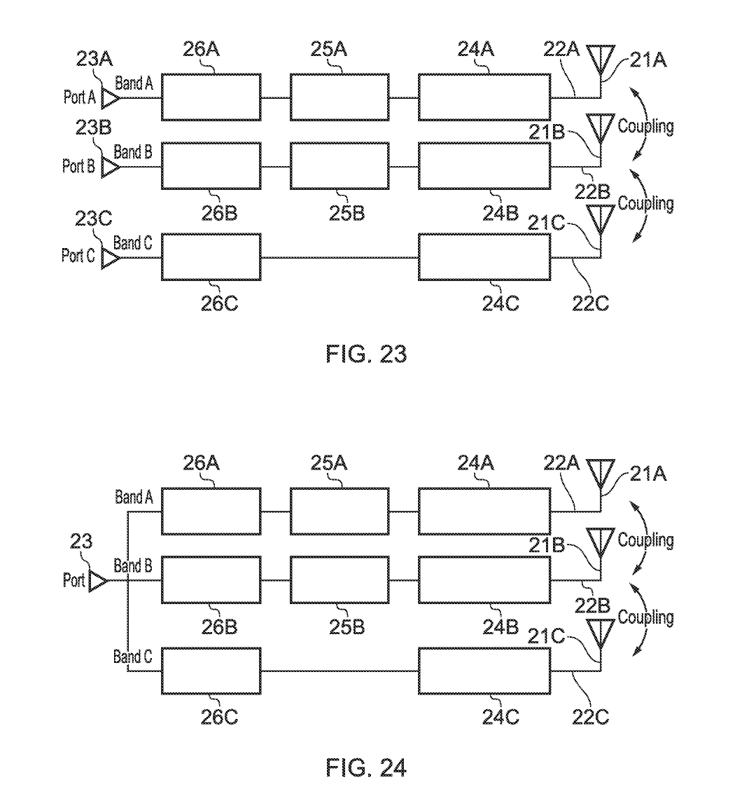

FIG. 23 shows a schematic outline of a first embodiment of the second aspect, in which a compound antenna comprising antenna radiating elements 21A, 21B and 21C has multiple feeds 22A, 22B and 22C. Feed 22A is connected to a transceiver port 23A by way of an active matching circuit comprising a pre-matching network 24A, a negative impedance converter network 25A and a post-matching network 26A. Feed 22B is connected to a transceiver port 23B by way of an active matching circuit comprising a pre-matching network 24B, a negative impedance converter network 25B and a post-matching network 26B. Feed 22C is connected to a transceiver port 23C by way of a passive matching circuit comprising a pre-matching network 24C and a post-matching network 26C. Transceiver port 23A is configured to handle a first frequency band A, transceiver port 23B is configured to handle a second frequency band B, and transceiver port 23C is configured to handle a third frequency band C. It will be appreciated that additional frequency bands can be accommodated by adding further antenna radiating elements, transceiver ports and matching circuits. While all embodiments will have at least one active branch comprising a pre-matching network, an NIC network and a post-matching network, some embodiments will comprise just active branches, and others may have one or more passive branches.

The antenna radiating elements 21A, 21B and 21C, which will generally be close together, for example in a mobile handset or other portable device, will tend to couple with each other during operation. In order to address this problem, the pre-matching networks 24 (and, in some embodiments, the post-matching networks 26) are configured to selectively decouple the matching circuits or branches across frequency bands of interest. In other words, coupling between antenna radiating elements, which is often unavoidable, can surprisingly be made unproblematic by appropriate configuration of the pre-matching networks 24 and, in some embodiments, the post-matching networks 26.

The pre-matching networks 24 have two functions. One is to decouple the multi-feed antenna 21 over all of the interesting frequency bands. Typically, after decoupling, the input impedance after the pre-matching network 24 in one branch can be independent of the circuits connected after the pre-matching networks 24 in the other branches. The other function of pre-matching network 24 is to transform the antenna impedance to a proper level so that the NIC network 25 can cancel the transformed reactance. Typically, the real part of the antenna impedance should be transformed to a higher, relatively flat level across the relevant frequency band, and the imaginary part of the antenna impedance should be transformed so that it increases monotonically from negative to positive across the relevant frequency band. The post-matching network 26 also has two functions. One is to match the impedance after cancellation by the NIC 25 (in an active branch) or the impedance after transformation (in a passive branch) to the impedance of the transceiver port 23 (normally 50 ohms). The other is to decouple different branches when all branches are connected to a single transceiver port 23, as shown in FIG. 24.

FIG. 24 shows an alternative embodiment, with like parts labelled as for FIG. 23. The embodiment of FIG. 24 is similar to that of FIG. 23, except that all of the branches connect to a single transceiver port 23, rather than to separate transceiver ports 23A, 23B and 23C.

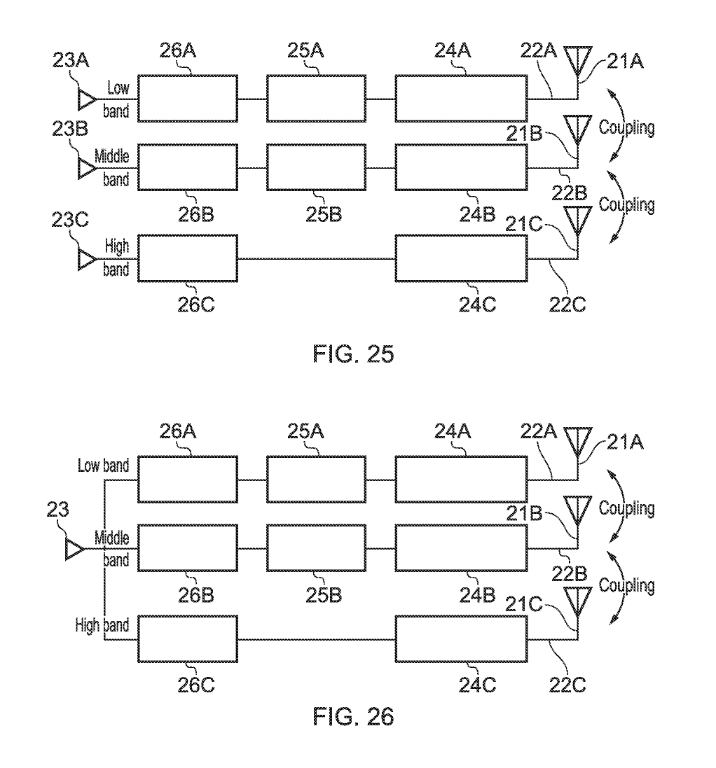

FIG. 25 shows a specific implementation of the embodiment of FIG. 23 to cover low, middle and high frequency bands, with parts being labelled as for FIG. 23. Antenna radiating element 21B and its associated matching circuitry 24B, 25B, 26B are configured for operation in a middle frequency band. Antenna radiating element 21C and its associated matching circuitry 24C, 26C are configured for operation in a high frequency band. Antenna radiating element 21A has the largest size, with antenna radiating element 21B having a middle size and antenna radiating element 21C having the smallest size. The input impedance of each antenna radiating element 21A, 21B, 21C is optimised for its respective frequency band by appropriate adjustment of the pre- and post-matching networks 24, 26. It will be noted that a mixture of active branches with NIC components 25 and passive branches with no NIC components may be provided in order to help fulfil desired bandwidth requirements.

Similarly, FIG. 26 shows a specific implementation of the embodiment of FIG. 24 to cover low, middle and high frequency bands, with parts being labelled as for FIG. 24.

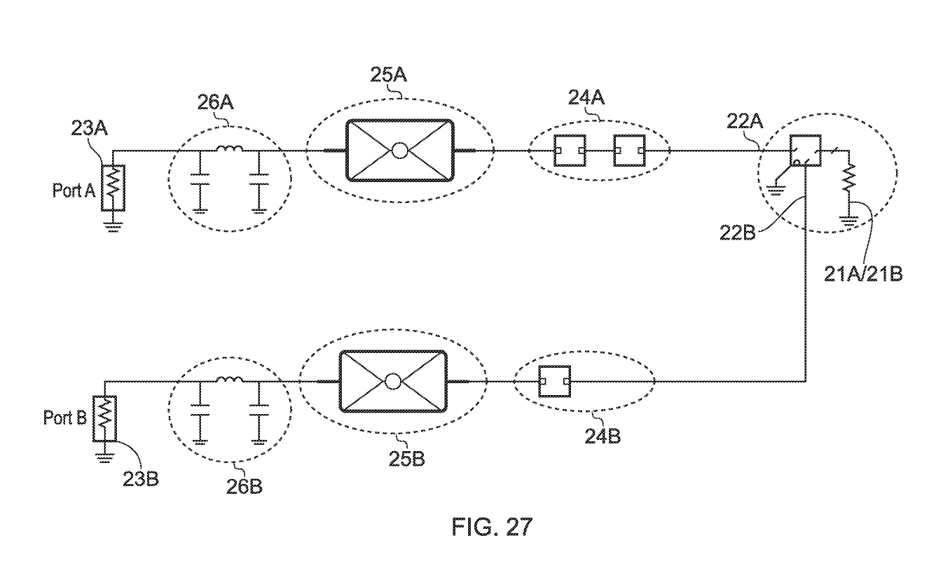

FIG. 27 shows a more detailed implementation of the embodiment of FIG. 23, comprising a multi-port NIC-based impedance matching circuit for a multi-feed antenna to cover multiple bands, with parts being labelled as in FIG. 23. The embodiment of FIG. 27 comprises first and second active branches, with no passive branch. Although the antenna radiating elements 21A, 21B are shown as a single component, this is merely a consequence of circuit diagram conventions. The multi-feed antenna will physically have different antenna radiating elements 21A, 21B.

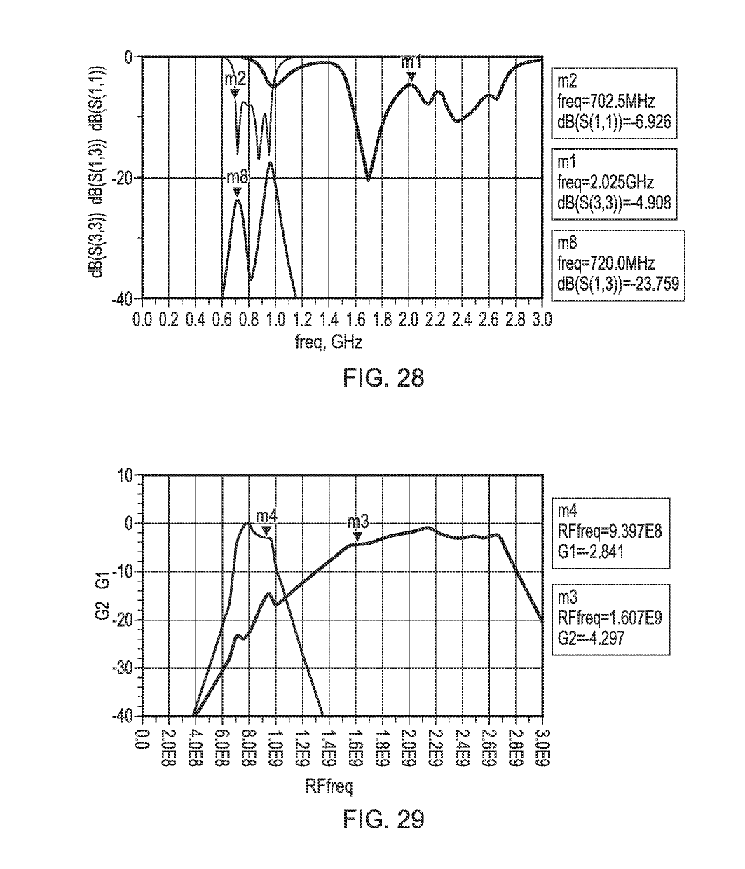

FIG. 28 shows the return loss at each transceiver port 23A, 23B of the FIG. 27 embodiment. It can be seen that transceiver port 23A can cover the LTE low band (700 MHz-960 MHz), and transceiver port 23B can cover the GNSS band and the LTE middle and high bands (1.56 GHz-2.7 GHz). The isolation between the two transceiver ports 23A, 23B is mostly lower than −18 dB. FIG. 29 shows the total efficiency of the antenna system over the two continuous wide frequency bands after matching.

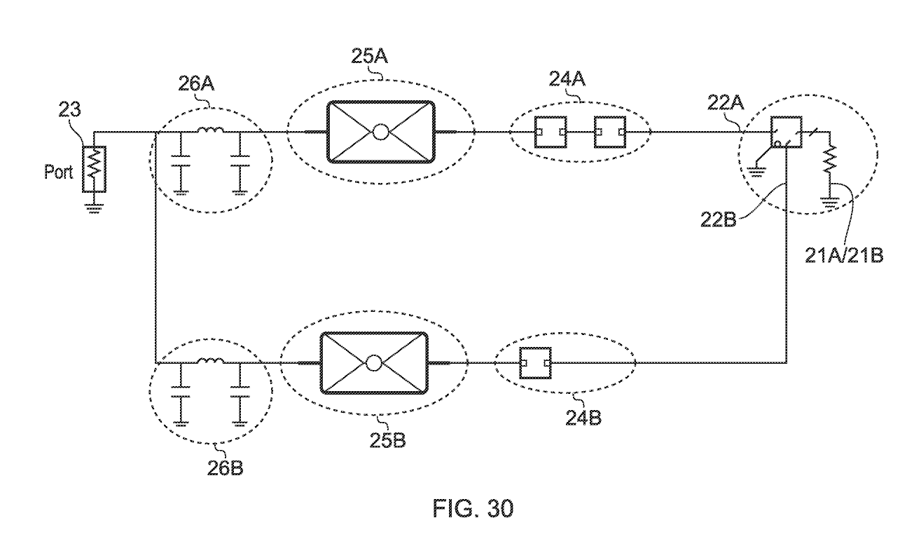

FIG. 30 shows a more detailed implementation of the embodiment of FIG. 24, comprising a single port NIC-based impedance matching circuit for a multi-feed antenna to cover multiple bands, with parts being labelled as in FIG. 24. The embodiment of FIG. 30 comprises first and second active branches, with no passive branch.

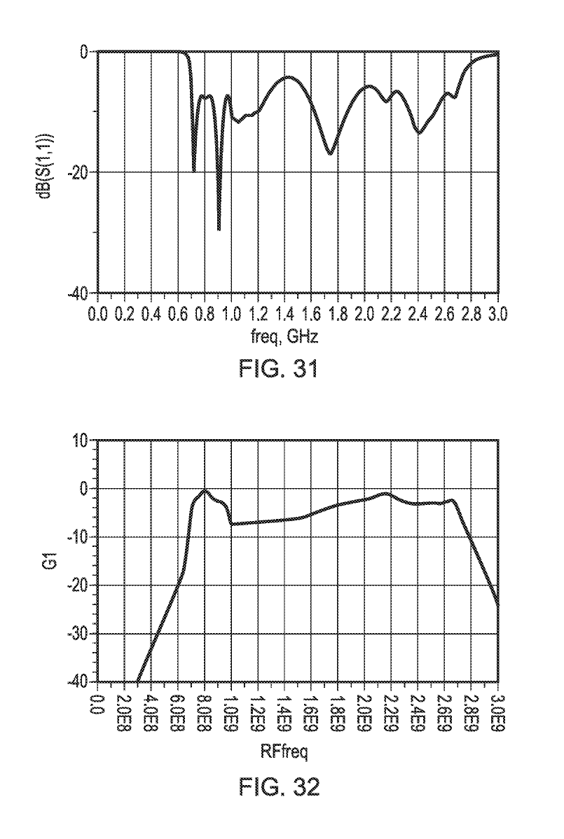

FIG. 31 shows the return loss at the transceiver port 23 of the FIG. 30 embodiment. It can be seen that the single transceiver port 23 can cover the LTE low band (700 MHz-960 MHz), GNSS band and the LTE middle and high bands (1.56 GHz-2.7 GHz) simultaneously. FIG. 32 shows the total efficiency of the antenna system over the two continuous wide frequency bands after matching.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

Features, integers, characteristics, compounds, chemical moieties or groups described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any foregoing embodiments. The invention extends to any novel one, or any novel combination, of the features disclosed in this specification (including any accompanying claims, abstract and drawings), or to any novel one, or any novel combination, of the steps of any method or process so disclosed.

The reader's attention is directed to all papers and documents which are filed concurrently with or previous to this specification in connection with this application and which are open to public inspection with this specification, and the contents of all such papers and documents are incorporated herein by reference.

1. A matching network for connecting an electrically small antenna to an RF source or load, the matching network comprising a negative impedance converter, a pre-matching network for connecting the negative impedance converter to the antenna and a post-matching network for connecting the negative impedance converter to the RF source or load, wherein the pre-matching network comprises a combination of capacitors and/or inductors to transform both a real part and an imaginary part of an impedance of the antenna, the negative impedance converter is configured substantially to cancel the transformed imaginary part of the impedance of the antenna, and wherein the post-matching network comprises a combination of capacitors and/or inductors to transform a residual real part of the impedance of the antenna to match an impedance of the RF source or load.

2. The matching network as claimed in claim 1, wherein the pre-matching network comprises at least one tuneable element.

3. The matching network as claimed in claim 2, wherein the at least one tuneable element is a tuneable or switchable capacitor.

4. The matching network as claimed in claim 1, wherein the negative impedance converter comprises at least one tuneable element.

5. The matching network as claimed in claim 4, wherein the at least one tuneable element is a tuneable or switchable capacitor.

6. The matching network as claimed in claim 1, wherein the post-matching network comprises at least one tuneable element.

7. The matching network as claimed in claim 6, wherein the at least one tuneable element is a tuneable or switchable capacitor.

8. The matching network as claimed in claim 1, wherein the pre-matching network is configured to transform an in-band real part of the antenna impedance to a higher level.

9. The matching network as claimed in claim 1, wherein the pre-matching network is configured to transform an in-band imaginary part of the antenna impedance to a lower level.

10. The matching network as claimed in claim 9, wherein the pre-matching network is configured to transform an in-band imaginary part of the antenna impedance to zero or substantially zero.

11. The matching network as claimed in claim 9, wherein the negative impedance converter is configured substantially to cancel the transformed imaginary part of the antenna impedance at an operational frequency or frequency band.

12. The matching network as claimed in claim 1, wherein the post-matching network is configured to transform a residual real part of the transformed antenna impedance to match an impedance of the RF source or load.

13. The matching network as claimed in claim 1, wherein the pre-matching network is configured to keep a real part of the transformed antenna impedance substantially flat or constant across an operational frequency band.

14. The matching network as claimed in claim 1, wherein the pre-matching network is configured so that an imaginary part of the transformed antenna impedance has a zero crossing frequency in an operational frequency band.

15. The matching network as claimed in claim 1, further comprising a system controller for tuning or switching the network or components thereof.

16. An antenna system comprising a plurality of antenna radiating elements each having an associated feed, at least one of the feeds being connected to an RF source or load by way of an active matching circuit comprising a pre-matching network, a negative impedance converter and a post-matching network; wherein the pre-matching network comprises a combination of capacitors and/or inductors to transform both a real part and an imaginary part of an impedance of the respective antenna feed.

17. The system of claim 16, wherein the RF source or load comprises at least one transceiver port.

18. The system of claim 16, wherein the RF source or load comprises at least one transmitter port.

19. The system of claim 16, wherein the RF source or load comprises at least one receiver port.

20. The system of claim 16, wherein the negative impedance converter is configured substantially to cancel the transformed imaginary part of the impedance of the respective antenna feed.

21. The system of claim 20, wherein the post-matching network comprises a combination of capacitors and/or inductors to transform a residual real part of the impedance of the antenna feed to match an impedance of the RF source or load.

22. The system of claim 16, wherein the pre-matching networks are configured to decouple the antenna radiating elements over the frequency bands of interest at any given time.

23. The system of claim 16, wherein all of the feeds are connected to the RF source or load by way of a respective active matching circuit comprising a negative impedance converter.

24. The system of claim 16, wherein at least one of the feeds is connected to the RF source or load by way of a passive matching circuit that does not include a negative impedance converter.

25. The system of claim 17, wherein the matching circuits are all connected to a single port.

26. The system of claim 17, wherein the matching circuits are all connected to different ports.

27. The system of claim 16, wherein each of the radiating antenna elements and their associated matching circuits are configured to operate in a predetermined continuous frequency band.

28. The system of claim 16, wherein the radiating antenna elements are sized differently to each other and/or have different electrical sizes.

29. (canceled)

30. (canceled)
